(19) United States
(12) Patent Application Publication
(10) Pub. No.: US 2024/0414919 A1
(43) Pub. Date: Dec. 12, 2024

(54) SUBSTRATE PROCESSING METHOD AND SUBSTRATE PROCESSING APPARATUS

(71) Applicants: SEMES CO., LTD., Cheonan-si (KR); Research & Business Foundation SUNGKYUNKWAN UNIVERSITY, Suwon-si (KR)

(72) Inventors: Sung Min CHOI, Cheonan-si (KR); Heeyeop CHAE, Seoul (KR); Hojin KANG, Suwon-si (KR); Hyeongwu LEE, Suwon-si (KR); Heeju HA, Suwon-si (KR)

(73) Assignees: SEMES CO., LTD., Cheonan-si (KR); Research & Business Foundation SUNGKYUNKWAN UNIVERSITY, Cheonan-si (KR)

(21) Appl. No.: 18/615,692

(22) Filed: Mar. 25, 2024

(30) Foreign Application Priority Data
Jun. 9, 2023 (KR) 10-2023-0074477

(51) Int. Cl. H10B 43/27; H01J 37/32

(52) U.S. Cl. CPC H10B 43/27; H01J 37/32449; H01J 37/32724; H01J 2237/2001; H01J 2237/334

(57) ABSTRACT

Proposed are a substrate processing method and a substrate processing apparatus. A substrate processing method according to an embodiment is for etching a thin film formed on a substrate at the atomic layer level, and includes a surface modification step of modifying a surface of the thin film by supplying a first gas including oxygen (O) to a processing space of a chamber in which the substrate is placed, a first purge step of removing the first gas remaining in the processing space by supplying a purge gas to the processing space, an etching step of etching the modified thin film by supplying a CHF₃ gas to the processing space, and a second purge step of removing the CHF₃ gas remaining in the processing space by supplying the purge gas to the processing space.

### CROSS-REFERENCE TO RELATED APPLICATION(S)

This application claims priority under 35 U.S.C. § 119 to Korean Patent Application No. 10-2023-0074477, filed on Jun. 9, 2023 in the Korean Intellectual Property Office, the disclosure of which is incorporated by reference herein in its entirety.

### BACKGROUND OF THE INVENTION

### Field of the Invention

The present disclosure relates generally to a substrate processing method and a substrate processing apparatus. More particularly, the present disclosure relates to a substrate processing method and a substrate processing apparatus for etching a tantalum nitride film at the atomic layer level.

### Description of the Related Art

With the increase in use of smartphones, tablet PCs, and solid state drives (SSDs), the demand for memory devices has increased rapidly. In particular, the need for low-power, highly integrated, and high-capacity flash memory is increasing.

In the case of conventional 2D structured flash memory, as the line width of cells decreases, interference between cells intensifies and leakage current occurs. As a solution to these problems, a 3D NAND flash structure in which cells are stacked vertically in three dimensions is gaining attention. This vertical stack structure allows more cells to be implemented in the same silicon area, which has the advantage of lowering manufacturing costs and increasing capacity.

The conventional 3D NAND flash has a structure formed by alternately stacking silicon oxide films and silicon nitride films and etching the stacked films to form source lines and word lines. FIG. 1 is a view partially illustrating the process of manufacturing 3D NAND flash. Referring to FIG. 1, 3D NAND flash can be manufactured by depositing various materials such as a tunneling oxide, a nitride film trap, a gate insulating layer, a barrier layer, and a gate in word lines, and then etching them to the formed nitride film trap. The recent trend of 3D NAND flash technology is increasing the number of layers to increase the capacity and making the pattern finer. Thus, in the 3D NAND flash manufacturing process, an importance of the etching process is increasingly recognized.

Among the above configurations, since the material constituting the gate, that is, metal, may cause device failure when it flows into a silicon oxide film or silicon nitride film, the barrier layer is provided to prevent the gate material from flowing into the silicon oxide or silicon nitride film. A common example of the material constituting the barrier layer is tantalum nitride. Generally, the barrier layer is formed by depositing a tantalum nitride film, and then etching the deposited tantalum nitride film through an etching process to make the film uniform.

Conventionally, the etching of the tantalum nitride film is achieved using a reactive ion etching (RIE) process. However, due to the difficulty in controlling the etching amount, an atomic layer etching (ALE) process has recently been used.

In this regard, a method of etching a tantalum nitride film using an atomic layer etching process is disclosed in Non-Patent Document 1. Non-Patent Document 1 describes an etching process in which a tantalum nitride film is oxidized with a material including oxygen to form a tantalum oxide film, the tantalum oxide film is modified with BCl₃ gas, and then the modified tantalum oxide film is etched with hydrogen fluoride (HF) gas. However, Non-Patent Document 1 does not provide any description regarding the properties of the etched tantalum nitride film, such as surface roughness and etching selectivity.

The foregoing is intended merely to aid in the understanding of the background of the present disclosure, and is not intended to mean that the present disclosure falls within the purview of the related art that is already known to those skilled in the art.

### Documents of Related Art

(Non-Patent document 1) Nicholas Johnson, ‘ATOMIC LAYER ETCHING OF METAL FILMS, METAL NITRIDESM AND METAL OXIDES WITH BCL₃ AND HF/XEF₂’: 2019

### SUMMARY OF THE INVENTION

Accordingly, the present disclosure has been made keeping in mind the above problems occurring in the related art, and an objective of the present disclosure is to provide a novel tantalum nitride film etching method that provides excellent etching selectivity to silicon oxide and silicon nitride films and secures small surface roughness even after etching, and to provide a substrate processing apparatus for the same.

The objectives of the present disclosure are not limited to those mentioned above, and other objectives not mentioned will be clearly understood by those skilled in the art from the following description.

In order to achieve the above objective, according to one aspect of the present disclosure, there is provided a substrate processing method for etching a thin film formed on a substrate at an atomic layer level, the substrate processing method including: a surface modification step of modifying a surface of the thin film by supplying a first gas including oxygen (O) to a processing space of a chamber in which the substrate is placed; a first purge step of removing the first gas remaining in the processing space by supplying a purge gas to the processing space; an etching step of etching the modified thin film by supplying a CHF₃ gas to the processing space; and a second purge step of removing the CHF₃ gas remaining in the processing space by supplying the purge gas to the processing space.

In one embodiment, a cycle including the surface modification step to the second purge step may be repeated at least 1 time.

In one embodiment, the thin film may be a tantalum nitride film.

In one embodiment, the substrate may include at least one of a silicon oxide film and a silicon nitride film.

In one embodiment, the substrate may include a stacked film in which the silicon oxide film and the silicon nitride film are alternately stacked, and the tantalum nitride film may be formed in an opening formed through the stacked film.

In one embodiment, the first gas may include at least one of O₂ and O₃.

In one embodiment, the surface modification step and the etching step may be performed in a state in which a plasma is generated in the processing space.

In one embodiment, the surface modification step to the second purge step may be performed in a state in which the substrate is heated to a predetermined temperature.

In one embodiment, the predetermined temperature may be 100° C. to 150° C.

According to another aspect of the present disclosure, there is provided a substrate processing apparatus, including: a chamber having a processing space therein; a substrate support unit disposed in the processing space, configured to support a substrate, and including a heating member configured to heat the substrate; a gas supply unit configured to supply a first gas including oxygen (O) and a CHF₃ gas to the processing space; a plasma generation unit configured to convert the gases supplied from the gas supply unit into a plasma state; and a control unit configured to control the gas supply unit and the plasma generation unit. The control unit may control the gas supply unit and the plasma generation unit so that a plasma of the first gas is generated in the processing space to modify a thin film formed on the substrate and a plasma of the CHF₃ gas is generated to etch the modified thin film formed on the substrate.

In one embodiment, the thin film may be a tantalum nitride film.

In one embodiment, the first gas may include at least one of O₂ and O₃.

In one embodiment, the substrate may include a stacked film in which a silicon oxide film and a silicon nitride film are alternately stacked, and the tantalum nitride film may be formed in an opening formed through the stacked film.

In one embodiment, the control unit may control the heating member to maintain a temperature of the substrate at 100° C. to 150° C.

According to another aspect of the present disclosure, there is provided a substrate processing method for etching a thin film formed on a substrate for manufacturing 3D NAND devices at an atomic layer level, the substrate processing method including: a surface modification step of modifying a surface of the thin film by supplying a first gas including oxygen (O) to a processing space of a chamber; a first purge step of removing the first gas remaining in the processing space by supplying a purge gas to the processing space; an etching step of etching the modified thin film by supplying a CHF₃ gas to the processing space; and a second purge step of removing the CHF₃ gas remaining in the processing space by supplying the purge gas to the processing space. The first gas may include at least one of O₂ and O₃, and one cycle defined from the surface modification step to the second purge step may be repeated at least 1 time and may be performed while maintaining the substrate at a temperature of 100° C. to 150° C.

In one embodiment, the thin film may be a tantalum nitride film.

In one embodiment, the substrate may include at least one of a silicon oxide film and a silicon nitride film.

In one embodiment, the substrate may include a stacked film in which the silicon oxide film and the silicon nitride film are alternately stacked vertically, and the tantalum nitride film may be formed in an opening formed through the stacked film.

In one embodiment, the substrate may include: a stacked film in which the silicon oxide film and the silicon nitride film are alternately stacked vertically; a slit-shaped first opening formed by etching the stacked film vertically; and a plurality of second openings formed to extend horizontally from the first opening by selectively etching the silicon nitride film exposed in the first opening. The tantalum nitride film may be formed on surfaces of the first opening and the second openings.

In one embodiment, a tunneling oxide may be formed along the surfaces of the first opening and the second openings, a nitride film trap may be formed on the tunneling oxide, a gate insulating film may be formed on the nitride film trap, and the tantalum nitride film may be formed on the gate insulating film.

According to the present disclosure, a tantalum nitride film formed on a substrate is modified with a first gas including oxygen (O) and the modified tantalum nitride film is etched with a CHF₃ gas at the atomic layer level.

In addition, by etching the tantalum nitride film at the atomic layer level using these gases, it is possible to achieve excellent etching selectivity to the silicon oxide film and silicon nitride film, and to reduce the surface roughness of the etched tantalum nitride film, thereby reducing device defects caused by leakage current.

The effects of the present disclosure are not limited to those mentioned above, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view partially illustrating the process of manufacturing 3D NAND flash;

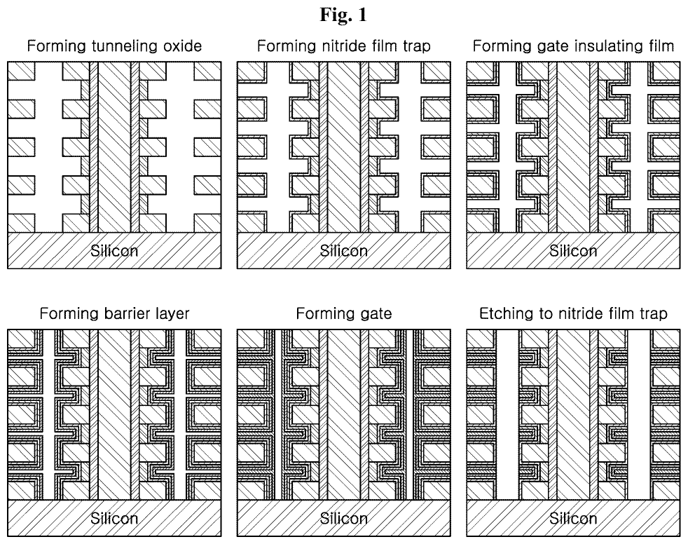

FIG. 2 is a flowchart illustrating a substrate processing method according to an embodiment of the present disclosure;

FIG. 3 is a schematic sectional view illustrating a substrate processing apparatus according to an embodiment of the present disclosure;

FIG. 4 is a graph illustrating the etch rate according to the temperature of a substrate according to the embodiment of the present disclosure;

FIG. 5 is a graph illustrating the thickness of a modified tantalum oxide film according to temperature according to the embodiment of the present disclosure;

FIG. 6 is a graph illustrating the surface roughness of an etched substrate according to the embodiment of the present disclosure; and

FIG. 7 is a graph illustrating the etching selectivity according to the type of substrate according to the embodiment of the present disclosure.

### DETAILED DESCRIPTION OF THE INVENTION

The present disclosure will now be described in detail with reference to the accompanying drawings so that those skilled in the art may easily practice the present disclosure. The present disclosure may, however, be embodied in many different forms and should not be construed as being limited to only the embodiments set forth herein.

In the following description, it is to be noted that, when the functions of conventional elements and the detailed description of elements related with the present disclosure may make the gist of the present disclosure unclear, a detailed description of those elements will be omitted. Wherever possible, the same reference numerals will be used throughout the drawings and the description to refer to the same or like elements or parts.

Technical terms, as will be mentioned hereinafter, are terms defined in consideration of their function in the present disclosure, which may be varied according to the intention of a user, practice, or the like. Thus, the terms should be defined on the basis of the contents of this specification.

As used herein, the singular forms are intended to include the plural forms as well, unless the context clearly indicates otherwise. It will be further understood that the terms “comprising” and/or “including” when used herein, specify the presence of stated features, integers, steps, operations, elements, and/or components, but do not preclude the presence or addition of one or more other features, integers, steps, operations, elements, components, and/or groups thereof.

In the figures, the size or shape of elements or the thickness of lines may be exaggerated for clarity of illustration.

Hereinafter, exemplary embodiments of the present disclosure will be described in detail with reference to the accompanying drawings, in which identical or similar constituent elements are given the same reference numerals regardless of the reference numerals of the drawings, and repeated description thereof will be omitted.

A substrate according to the embodiment of the present disclosure is a silicon substrate on which a silicon oxide film or silicon nitride film is formed, and a thin film may be formed on the silicon oxide film or silicon nitride film. The thin film may be a tantalum nitride film, but is not limited thereto.

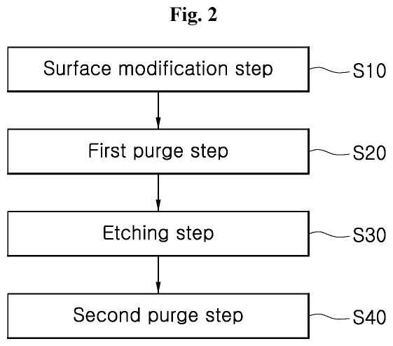

FIG. 2 is a flowchart illustrating a substrate processing method according to an embodiment of the present disclosure.

Referring to FIG. 2, the substrate processing method is for etching a thin film formed on a substrate at the atomic layer level, and may include: a surface modification step S10 of modifying a surface of the thin film by supplying a first gas including oxygen (O) to a processing space of a chamber in which the substrate is placed; a first purge step S20 of removing the first gas remaining in the processing space by supplying a purge gas to the processing space; an etching step S30 of etching the modified thin film by supplying a CHF₃ gas to the processing space; and a second purge step S40 of removing the CHF₃ remaining in the processing space by supplying the purge gas to the processing space. The sequence of the surface modification step S10 to the second purge step S40 is defined as one cycle. This cycle may be repeated at least 1 time to etch the thin film formed on the substrate to a desired thickness.

The surface modification step S10 is a step of modifying the surface of the thin film by supplying the first gas including oxygen (O). The first gas including oxygen (O) may be supplied from a gas supply unit. The supplied first gas may be converted into a plasma state and supplied to the substrate. The first gas in the plasma state may undergo a chemical reaction with the thin film formed on the substrate, thereby modifying the surface layer of the thin film. The first gas may include at least one of O₂ and O₃. The first gas according to the embodiment of the present disclosure is O₂ gas, but is not limited thereto. In the surface modification step S10, a surface of a tantalum nitride film formed on a silicon oxide film or silicon nitride film may be modified at the atomic layer or molecular layer level. For example, the surface layer of the tantalum nitride film may react with a plasma of O₂ gas and be modified into a tantalum oxide (TaₓO_{y}) film.

The first purge step S20 is a step of removing the first gas remaining in the processing space inside the chamber by supplying the purge gas from the gas supply unit. The purge gas may be supplied after the supply of the first gas is stopped, and may be supplied directly to the processing space inside the chamber without the use of plasma. Due to the supply of the purge gas, the first gas, which is supplied in the surface modification step S10 and remains in the processing space inside the chamber, and reaction by-products may be removed from the processing space. As the purge gas, an inert gas such as argon (Ar), helium (He), or nitrogen (N₂) may be used.

The etching step S30 is a step of etching the modified thin film by supplying the CHF₃ gas. In the etching step S30, the CHF₃ gas supplied from the gas supply unit may be converted into a plasma state, and the modified thin film may be etched with a plasma of the CHF₃ gas. The CHF₃ gas radicalized and ionized by a plasma generation unit may etch the thin film formed on the substrate at the atomic or molecular layer level through a ligand exchange reaction with the surface of the modified thin film while generating volatile etching by-products. According to the embodiment of the present disclosure, the tantalum oxide film modified in the surface modification step S10 may be etched at the atomic or molecular layer level by reacting with the plasma of the CHF₃ gas while generating volatile tantalum fluoride (TaFₓ) and oxygen. In addition, a part of the CHF₃ gas remaining after reacting with the modified tantalum oxide film may adhere to the surface layer of the tantalum nitride film to form fluorocarbon (CₓF_{y}). This fluorocarbon may be formed roughly on the surface layer of the tantalum nitride film, and may then be removed by an oxygen (O₂) plasma supplied in the surface modification step S10.

The second purge step S40 is a step of removing the CHF₃ gas remaining in the processing space inside the chamber by supplying the purge gas from the gas supply unit. The purge gas may be supplied after the supply of the CHF₃ gas is stopped, and may be supplied directly to the processing space inside the chamber without the use of plasma. Due to the supply of the purge gas, the CHF₃ gas, which is supplied in the etching step S30 and remains in the processing space inside the chamber, and etching by-products may be removed from the processing space. As the purge gas, an inert gas such as argon (Ar), helium (He), or nitrogen (N₂) may be used.

The substrate processing method according to the embodiment of the present disclosure may be performed by heating the substrate. The substrate may be heated by a heating member of a substrate support unit supporting the substrate. Here, the temperature of the substrate may be in the range of 100° C. to 150° C.

As described above, in order to etch the thin film, that is, the tantalum nitride film, formed on the substrate using the substrate processing method of the present disclosure at the atomic layer level, the tantalum nitride film formed on the substrate, may be modified with a plasma of O₂, which is the first gas, and the modified tantalum nitride film may be etched with a plasma of CHF₃ at the atomic or molecular layer level.

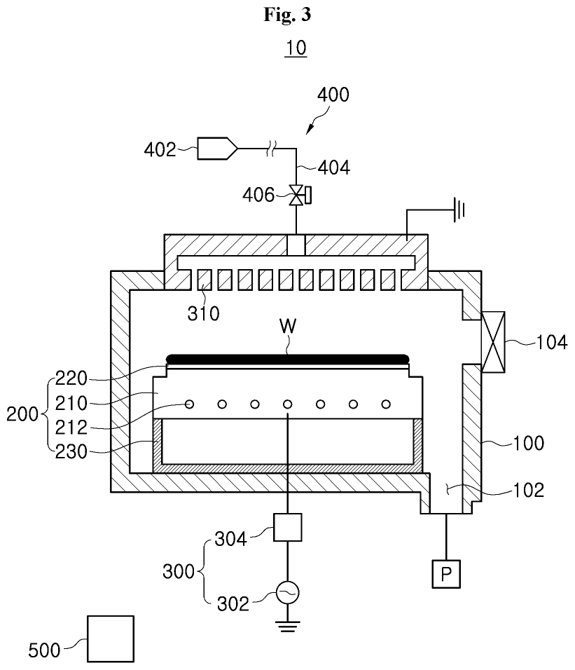

FIG. 3 is a view illustrating a substrate processing apparatus 10 according to an embodiment of the present disclosure.

Referring to FIG. 3, the substrate processing apparatus 10 according to the embodiment of the present disclosure may include a chamber 100, a substrate support unit 200, a plasma generation unit 300, a gas supply unit 400, and a control unit 500.

The chamber 100 has a processing space where a plasma process is performed. The chamber 100 may have an exhaust port 102 at a lower portion thereof. The exhaust port 102 may be connected to an exhaust line on which a pump P is mounted. The exhaust port 102 may discharge reaction by-products generated during a plasma process and gas remaining inside the chamber 100 to the outside of the chamber 100 through the exhaust line. In this case, the internal space of the chamber 100 may be depressurized to a predetermined pressure.

The chamber 100 may have an opening 104 on a side wall thereof. The opening 104 may function as a passage through which a substrate W enters and exits the chamber 100. The opening 104 may be configured to be opened and closed by a door assembly.

The substrate support unit 200 may be disposed in a lower area inside the chamber 100. The substrate support unit 200 may support the substrate W using electrostatic force. However, the present disclosure is not limited thereto, and the substrate W may be supported by various methods, such as mechanical clamping and vacuum.

The substrate support unit 200 may include a support body 210 and an electrostatic chuck 220 disposed on the support body 210. The electrostatic chuck 220 may be configured to electrostatically adsorb the substrate W, and may include ceramic layers with an electrode interposed therebetween.

According to the embodiment of the present disclosure, a heating member 212 may be provided inside the support body 210. The heating member 212 may heat the substrate W to a preset temperature. For example, the heating member 212 may be a heating coil, but is not limited thereto.

A support member 230 may be provided under the support body 210 to support the support body 210 and the electrostatic chuck 220. The support member 230 may have a cylindrical shape with a predetermined height and may have a space therein.

The plasma generation unit 300 may generate a plasma in the processing space of the chamber 100. The plasma may be formed in an upper area of the substrate support unit 200 inside the chamber 100. According to the embodiment of the present disclosure, the plasma generation unit 300 may generate a plasma in the processing space inside the chamber 100 using a capacitively coupled plasma (CCP) source.

However, the present disclosure is not limited thereto. The plasma generation unit 300 may generate a plasma in the processing space inside the chamber 100 using another type of plasma source, such as an inductively coupled plasma (ICP) source or a microwave.

The plasma generation unit 300 may include a high-frequency power source 302 and a matcher 304. The high-frequency power source 302 may supply high-frequency power to cither an upper electrode or a lower electrode to generate a potential difference between the upper electrode and the lower electrode. Here, the upper electrode may be a showerhead 310, and the lower electrode may be the substrate support unit 200. The high-frequency power source 302 may be connected to the lower electrode, and the upper electrode may be grounded.

The showerhead 310 may be formed to vertically face the electrostatic chuck 220 inside the chamber 100. The showerhead 310 may be provided with a plurality of gas spray holes to evenly spray gas into the chamber 100, and may have a larger diameter than the electrostatic chuck 220. Meanwhile, the showerhead 310 may be manufactured using a silicon material, and may also be manufactured using a metal material.

The gas supply unit 400 may supply a gas required for the process to the processing space of the chamber 100. The gas supply unit 400 may include a gas source 402, a gas supply line 404, and a gas spray nozzle. The gas supply line 404 may connect the gas source 402 and the gas spray nozzle to each other. A valve 406 may be installed in the gas supply line 404 to open and close a passage of the gas supply line 404 or to control the flow rate of fluid flowing through the passage.

FIG. 3 illustrates only one gas source 402 and one gas supply valve 406, but the present disclosure is not limited thereto. For example, a plurality of gas sources 402 may be provided to supply a plurality of gases to the chamber 100, and a plurality of gas supply valves may be provided to independently control the supply of each gas. The plurality of gases are gases used to modify the substrate W or to etch the modified substrate W, may include, for example, a first gas for modifying a surface of a thin film formed on the substrate W, a second gas for etching the modified thin film, and an inert gas for purging. The first gas is a gas including oxygen (O) and may include any one of O₂ and O₃, and the second gas is a gas including fluorine (F) and may be CHF₃.

The control unit 500 may comprehensively control the operation of the substrate processing apparatus 10 configured as described above. The control unit 500 is, for example, a computer and may include a central process unit (CPU), random access memory (RAM), read only memory (ROM), and auxiliary memory. The CPU may operate on the basis of programs or process conditions stored in the ROM or auxiliary memory and control the entire operation of the apparatus 10.

The control unit 500 according to the embodiment of the present disclosure may control so that the first gas and the second gas are supplied to the processing space inside the chamber 100 and the first gas and the second gas are converted into a plasma state by the plasma generation unit 300. In addition, the control unit 500 may control the heating member 212 of the substrate support unit 200 to maintain the temperature of the substrate W in the range of 125° C. to 175° C.

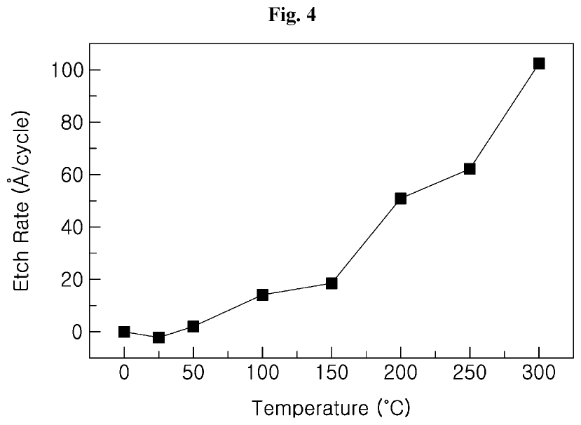

Next, experimental examples in which an atomic layer etching process was performed using the substrate processing apparatus illustrated in FIG. 3 will be described. FIGS. 4 to 7 are graphs illustrating experimental examples according to an embodiment of the present disclosure.

In the experimental examples according to the embodiment of the present disclosure, an etching process was performed on a silicon substrate including a silicon oxide film of about 200 nm formed thereon and a tantalum nitride film of about 50 nm formed on the silicon oxide film.

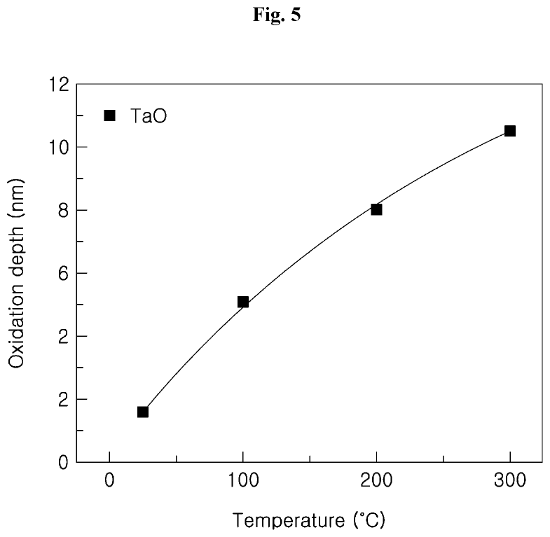

FIG. 4 is a graph illustrating the etch rate according to the temperature of a substrate according to the embodiment of the present disclosure. FIG. 5 is a graph illustrating the thickness of a modified tantalum oxide film according to temperature according to the embodiment of the present disclosure. To evaluate the etch rate of the tantalum nitride film according to the temperature of the substrate, the etch rate according to temperature was measured while changing the temperature of the substrate from 0° C. to 300° C. under the conditions in Table 1 below. Here, the etching process was performed for 10 cycles for each temperature of the substrate.

TABLE 1

Process conditions

| | | | |
|---|---|---|---|
| Surface modification step | Pressure | 50 | mTorr |
| (S10) | Time | 300 | sec |
| First purge step | Time | 60 | sec |
| (S20) | | | |
| Etching step | Pressure | 50 | mTorr |
| (S30) | Time | 60 | sec |
| Second purge step | Time | 60 | sec |
| (S40) | | | |

Referring to FIG. 4, when the temperature of the substrate is 0° C. to 25° C., the tantalum nitride film is not etched.

When the temperature of the substrate is 50° C., the tantalum nitride film is very slightly etched, and the etching amount is about 0.1 Å per cycle.

When the temperature of the substrate is 100° C., the etching amount of the tantalum nitride film is about 16 Å per cycle.

When the temperature of the substrate is 150° C., the etching amount of the tantalum nitride film is about 19 Å per cycle.

When the temperature of the substrate is 200° C., the etching amount of the tantalum nitride film is about 50 Å per cycle.

When the temperature of the substrate is 250° C., the etching amount of the tantalum nitride film is about 60 Å per cycle.

When the temperature of the substrate is 300° C., the etching amount of the tantalum nitride film is about 100 Å per cycle.

That is, it can be found that the etch rate of the tantalum nitride film continues to increase with temperature. As illustrated in FIG. 5, this may be due to the fact that in the process of modifying the tantalum nitride film into the tantalum oxide film by a first gas, O₂, the surface layer of the tantalum nitride film is not saturated as the temperature changes and the thickness of the tantalum oxide film continues to increase.

In view of the above experimental results, it is preferable to etch the tantalum nitride film at a temperature of 100° C. to 150° C. to facilitate control of the etch rate. At temperatures lower than 100° C., the etch rate is too small, and at temperatures higher than 150° C., the etch rate change due to temperature change is relatively large, making it difficult to control the etch rate.

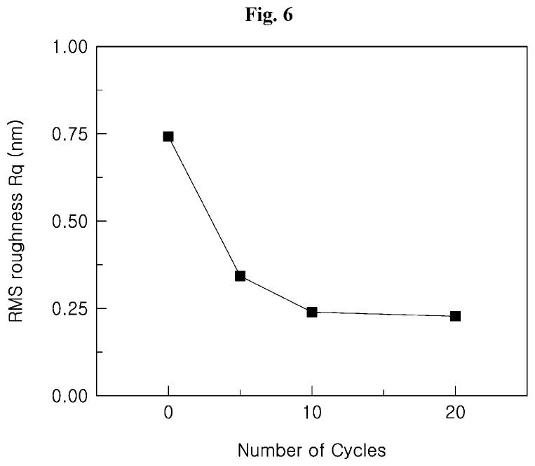

FIG. 6 is a graph illustrating the surface roughness of the etched tantalum nitride film per cycle. The surface roughness of the etched tantalum nitride film was measured under the conditions in Table 2 below.

TABLE 2

| | Process conditions | | | Temperature |
|---|---|---|---|---|
| Surface modification step | Pressure | 50 | mTorr | 100° C. |
| (S10) | Time | 180 | sec | |
| First purge step | Time | 60 | sec | |
| (S20) | | | | |
| Etching step | Pressure | 50 | mTorr | |
| (S30) | Time | 120 | sec | |
| Second purge step | Time | 60 | sec | |
| (S40) | | | | |

To evaluate the surface roughness of the tantalum nitride film, the root mean square roughness was measured using an atomic force microscope (AFM).

Referring to FIG. 6, when the etching process is not performed on the substrate, the surface roughness of the tantalum nitride film is about 0.75 nm.

When the etching process is performed for 5 cycles under the conditions in Table 2, the surface roughness of the etched tantalum nitride film is about 0.35 nm.

When the etching process is performed for 10 cycles, the surface roughness of the etched tantalum nitride film is about 0.25 nm, and when the etching process is performed for 20 cycles, the surface roughness of the etched tantalum nitride film is about 0.23 nm.

That is, it can be found that in the case of the etched tantalum nitride film, the surface roughness is reduced by about 3% per cycle. This indicates that the surface of the etched tantalum nitride film is even.

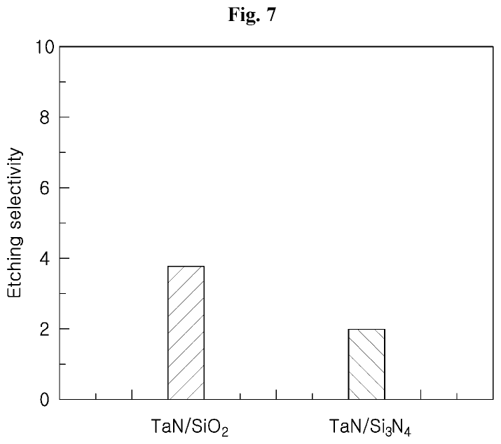

FIG. 7 is a graph illustrating the etching selectivity according to the type of substrate. According to the embodiment of the present disclosure, the substrate may include a silicon oxide film or a silicon nitride film, and a tantalum nitride film may be formed on the silicon oxide film or silicon nitride film. An etching process was performed on a silicon substrate including a silicon nitride film of about 200 nm formed thereon and a tantalum nitride film of about 50 nm formed on the silicon nitride film.

To evaluate the etching selectivity of the tantalum nitride film formed on the silicon oxide film and the etching selectivity of the tantalum nitride film formed on the silicon nitride film, the etching process was performed for 10 cycles under the conditions in Table 2 above and then the etching selectivity according to the type of substrate was confirmed.

Referring to FIG. 7, in the case of the tantalum nitride film formed on the silicon oxide film, the etching selectivity to the silicon oxide film is 3.8. Also, in the case of the tantalum nitride film formed on the silicon nitride film, the etching selectivity to the silicon nitride film is 2. This indicates that the etching method according to the embodiment of the present disclosure enables the tantalum nitride film to be selectively etched while minimizing etching of the silicon oxide film or silicon nitride film.

As can be seen from the above experimental results, the tantalum nitride film formed on the silicon oxide film or silicon nitride film is etched by modifying the tantalum nitride film with the first gas including oxygen (O) and etching the modified tantalum nitride film with the CHF₃ gas at the atomic layer level.

In addition, by using the first gas and the CHF₃ gas, it is possible to reduce the surface roughness of the etched tantalum nitride film, thereby reducing device defects caused by leakage current.

Moreover, by selectively etching the tantalum nitride film to the silicon oxide film and silicon nitride film, it is possible to achieve excellent etching selectivity. Based on the above-described advantages, the present disclosure can be applied to various processes.

Although the exemplary embodiments of the present disclosure have been described for illustrative purposes, those skilled in the art will appreciate that various modifications, additions, and substitutions are possible, without departing from the scope and spirit of the present disclosure. Therefore, the exemplary embodiments of the present disclosure have not been described for limiting purposes, and the scope of the disclosure is not to be limited by the above embodiments. The scope of the present disclosure should be determined on the basis of the descriptions in the appended claims, and all equivalents thereof should belong to the scope of the present disclosure.

What is claimed is:

1. A substrate processing method for etching a thin film formed on a substrate at an atomic layer level, the substrate processing method comprising:
a surface modification step of modifying a surface of the thin film by supplying a first gas including oxygen (O) to a processing space of a chamber in which the substrate is placed;
a first purge step of removing the first gas remaining in the processing space by supplying a purge gas to the processing space;
an etching step of etching the modified thin film by supplying a CHF₃ gas to the processing space; and
a second purge step of removing the CHF₃ gas remaining in the processing space by supplying the purge gas to the processing space.

2. The substrate processing method of claim 1, wherein a cycle including the surface modification step to the second purge step is repeated at least 1 time.

3. The substrate processing method of claim 1, wherein the thin film is a tantalum nitride film.

4. The substrate processing method of claim 3, wherein the substrate includes at least one of a silicon oxide film and a silicon nitride film.

5. The substrate processing method of claim 4, wherein the substrate includes a stacked film in which the silicon oxide film and the silicon nitride film are alternately stacked,
wherein the tantalum nitride film is formed in an opening formed through the stacked film.

6. The substrate processing method of claim 1, wherein the first gas includes at least one of O₂ and O₃.

7. The substrate processing method of claim 1, wherein the surface modification step and the etching step are performed in a state in which a plasma is generated in the processing space.

8. The substrate processing method of claim 1, wherein the surface modification step to the second purge step are performed in a state in which the substrate is heated to a predetermined temperature.

9. The substrate processing method of claim 8, wherein the predetermined temperature is 100° C. to 150° C.

10. A substrate processing apparatus, comprising:
a chamber having a processing space therein;
a substrate support unit disposed in the processing space, configured to support a substrate, and including a heating member configured to heat the substrate;
a gas supply unit configured to supply a first gas including oxygen (O) and a CHF₃ gas to the processing space;
a plasma generation unit configured to convert the first gas supplied from the gas supply unit into a plasma state; and
a control unit configured to control the gas supply unit and the plasma generation unit,
wherein the control unit controls the gas supply unit and the plasma generation unit so that a plasma of the first gas is generated in the processing space to modify a thin film formed on the substrate and a plasma of the CHF₃ gas is generated to etch the modified thin film formed on the substrate.

11. The substrate processing apparatus of claim 10, wherein the thin film is a tantalum nitride film.

12. The substrate processing apparatus of claim 10, wherein the first gas includes at least one of O₂ and O₃.

13. The substrate processing apparatus of claim 11, wherein the substrate includes a stacked film in which a silicon oxide film and a silicon nitride film are alternately stacked,
wherein the tantalum nitride film is formed in an opening formed through the stacked film.

14. The substrate processing apparatus of claim 10, wherein the control unit controls the heating member to maintain a temperature of the substrate at 100° C. to 150° C.

15. A substrate processing method for etching a thin film formed on a substrate for manufacturing 3D NAND devices at an atomic layer level, the substrate processing method comprising:
a surface modification step of modifying a surface of the thin film by supplying a first gas including oxygen (O) to a processing space of a chamber;
a first purge step of removing the first gas remaining in the processing space by supplying a purge gas to the processing space;
an etching step of etching the modified thin film by supplying a CHF₃ gas to the processing space; and
a second purge step of removing the CHF₃ gas remaining in the processing space by supplying the purge gas to the processing space,
wherein the first gas includes at least one of O₂ and O₃, and
one cycle defined from the surface modification step to the second purge step is repeated at least 1 time and is performed while maintaining the substrate at a temperature of 100° C. to 150° C.

16. The substrate processing method of claim 15, wherein the thin film is a tantalum nitride film.

17. The substrate processing method of claim 16, wherein the substrate includes at least one of a silicon oxide film and a silicon nitride film.

18. The substrate processing method of claim 17, wherein the substrate includes a stacked film in which the silicon oxide film and the silicon nitride film are alternately stacked vertically,
wherein the tantalum nitride film is formed in an opening formed through the stacked film.

19. The substrate processing method of claim 17, wherein the substrate includes:
a stacked film in which the silicon oxide film and the silicon nitride film are alternately stacked vertically;
a slit-shaped first opening formed by etching the stacked film vertically; and
a plurality of second openings formed to extend horizontally from the slit-shaped first opening by selectively etching the silicon nitride film exposed in the slit-shaped first opening,
wherein the tantalum nitride film is formed on surfaces of the slit-shaped first opening and the second openings.

20. The substrate processing method of claim 19, wherein a tunneling oxide is formed along the surfaces of the slit-shaped first opening and the second openings,
a nitride film trap is formed on the tunneling oxide,
a gate insulating film is formed on the nitride film trap, and
the tantalum nitride film is formed on the gate insulating film.
